(19) United States
(12) Patent Application Publication
(10) Pub. No.: US 2011/0316402 A1
(43) Pub. Date: Dec. 29, 2011

(54) SERVER CABINET

(75) Inventor: YI-LIANG HSIAO, Tu-Cheng (TW)

(73) Assignee: HON HAI PRECISION INDUSTRY CO., LTD., Tu-Cheng (TW)

(21) Appl. No.: 12/862,715

(22) Filed: Aug. 24, 2010

(30) Foreign Application Priority Data
Jun. 29, 2010 (TW) 99121343

(51) Int. Cl. H05K 5/02; E05C 19/10

(52) U.S. Cl. 312/326

(57) ABSTRACT

An exemplary server cabinet includes a rack adapted to accommodate a plurality of servers therein and a side door. The rack includes two supporting posts. The side door is mounted between the two supporting posts. A pair of latch hooks and a pair of fastening plates corresponding to the latch hooks are formed between the side door and the supporting posts. During assembly of the side door to the rack, the side door slides between the two supporting posts with two opposite sides of the side door abutting the two supporting posts, respectively, until the fastening plates are received in the latch hooks respectively and the side door is thereby engaged between the two supporting posts.

### BACKGROUND

1. Technical Field

The present disclosure relates to a server cabinet providing convenient assembling and disassembling.

2. Description of Related Art

Computer server systems often include multiple standard servers mounted in a standard server cabinet. Each server is a standalone computer that can include many electronic components, such as one or more processors, random-access memory (RAM), fixed disks, alternating current to direct current (AC to DC) power supplies, and others. For unified management, the servers are arranged in the server cabinet one-by-one in order from bottom to top.

A server cabinet is generally rectangular (cuboid), and includes a rack and side door mounted on one side of the rack. The rack defines a hollow cuboid receiving space for receiving the servers therein. A plurality of through holes is defined in one side of the side door. The rack forms threads corresponding to the through holes of the side door. Fasteners extend through the through holes of the side door and thread with the rack, thereby attaching the side door to the rack. However, assembly and detachment of the side door require a tool, such as a screwdriver, rendering the processes cumbersome and time-consuming.

It is thus desirable to provide a server cabinet which can overcome the described limitations.

### BRIEF DESCRIPTION OF THE DRAWINGS

FIG. 1 is an isometric, exploded view of a server cabinet in accordance with an exemplary embodiment of the present disclosure, wherein the server cabinet includes a rack and two side doors.

FIG. 2 is an isometric, assembled view of the server cabinet of FIG. 1.

FIG. 3 is an enlarged view of a circled portion III of FIG. 1.

FIG. 4 is an enlarged view of a circled portion IV of FIG. 1.

FIG. 5 is an enlarged view of a circled portion V of FIG. 1.

FIG. 6 is similar to FIG. 1, showing assembly of one of the side doors to the rack.

### DETAILED DESCRIPTION

Reference will now be made to the drawing figures to describe an exemplary embodiment of the present server cabinet in detail.

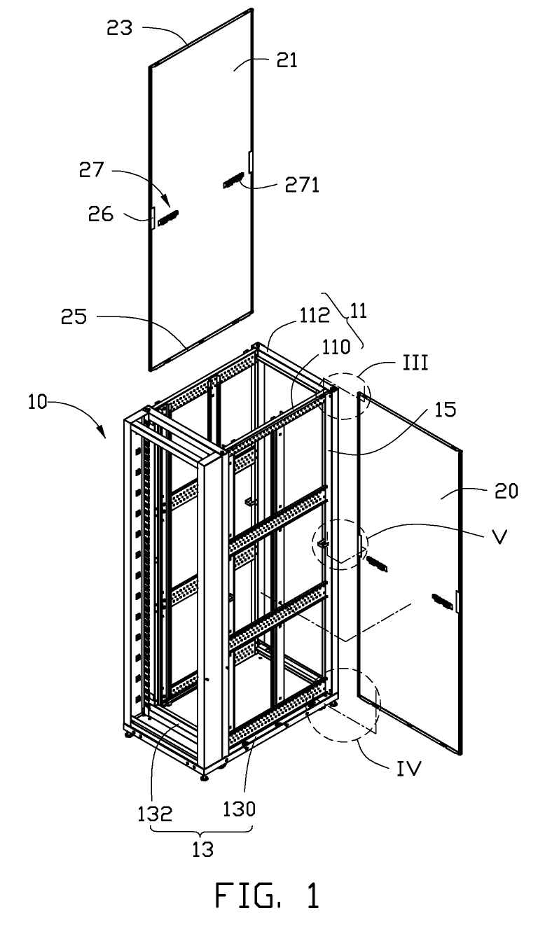

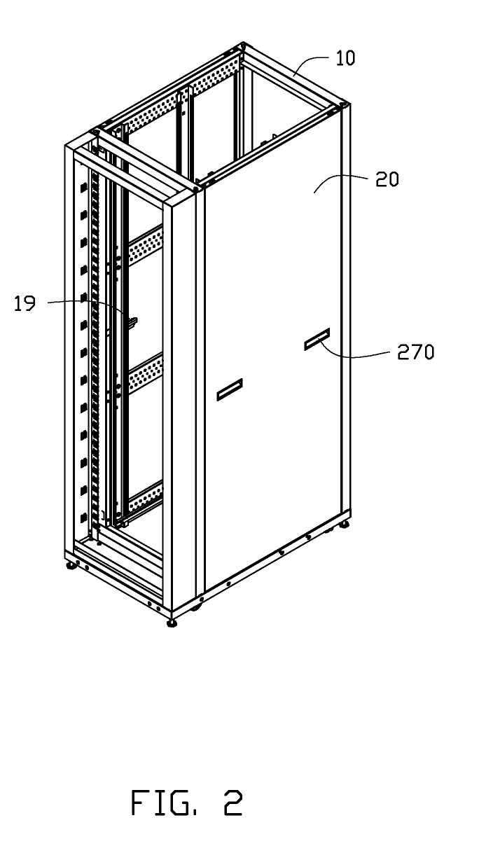

Referring to FIGS. 1 and 2, a server cabinet 100 according to an exemplary embodiment of the present disclosure is shown. The server cabinet 100 includes a rack 10, and two side doors 20 mounted on two opposite sides of the rack 10, respectively.

The rack 10 includes a rectangular top frame 11, an opposite rectangular bottom frame 13, and four supporting posts 15 between the top frame 11 and the bottom frame 13. The top frame 11 includes two elongated first angle frames 110 and two elongated second angle frames 112. The first angle frames 110 are parallel to and spaced apart from each other. The second angle frames 112 are parallel to and spaced apart from each other, and are connected between two opposite ends of the first angle frames 110, respectively. The first angle frames 110 are longer than the second angle frames 112.

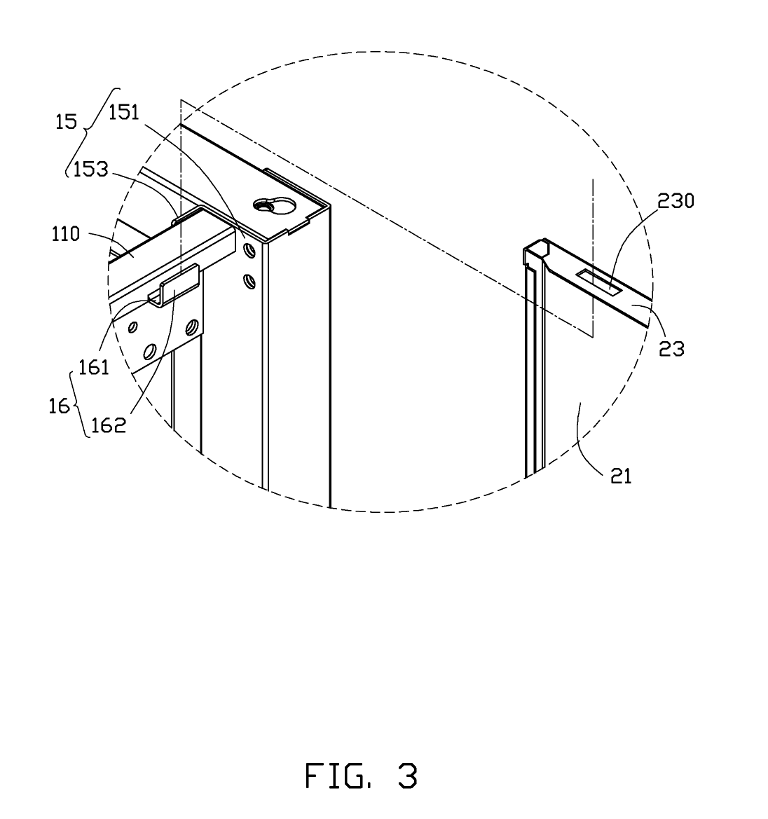

Referring also to FIG. 3, each of the first angle frames 110 includes two fastening tabs 16 adjacent to two opposite ends thereof, respectively. Each of the fastening tabs 16 includes a horizontal strip 161 extending outward and horizontally from an outer side of a corresponding first angle frame 110, and a vertical strip 162 extending up from a distal end of the horizontal strip 161. Each of the fastening tabs 16 is substantially L-shaped.

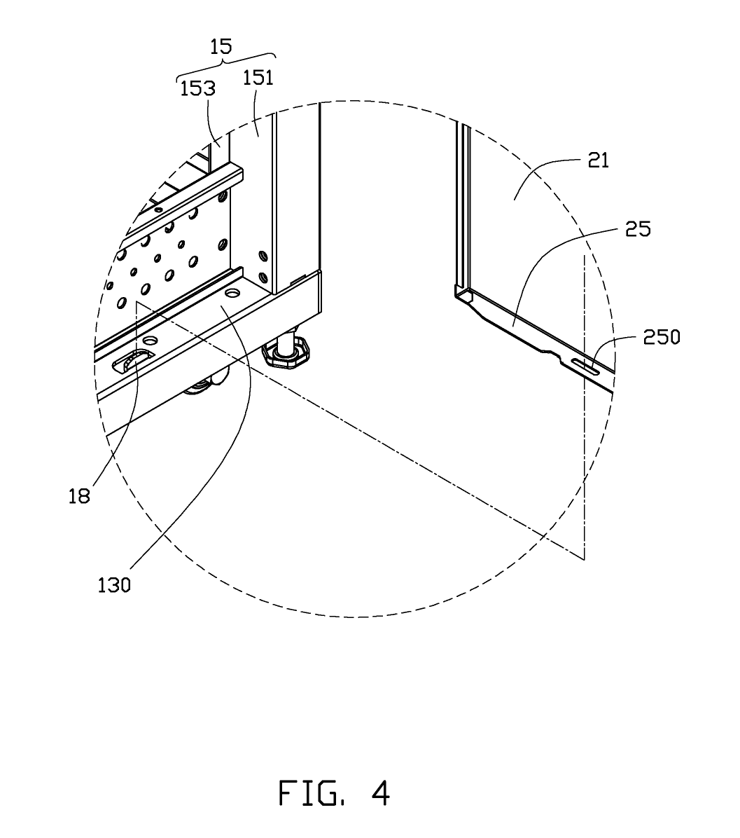

Referring to FIG. 1 again, the bottom frame 13 includes two elongated third angle frames 130 and two elongated fourth angle frames 132. The third angle frames 130 are parallel to and spaced apart from each other. The fourth angle frames 132 are connected between two opposite ends of the third angle frames 130, respectively. The third angle frames 130 are longer than the fourth angle frames 110. The third angle frames 130 align with the first angle frames 110, respectively. The fourth angle frames 132 align with the second angle frames 112, respectively. Referring also to FIG. 4, each of the third angle frames 130 includes a plurality of connecting strips 18 extending upwardly therefrom. Each of the connecting strips 18 is substantially semicircular. The connecting strips 18 of one of the third angle frames 130 and the vertical strips 162 of the fastening tabs 16 of one of the first angle frames 110 located on the same side (front side or rear side) of the rack 10 are coplanar.

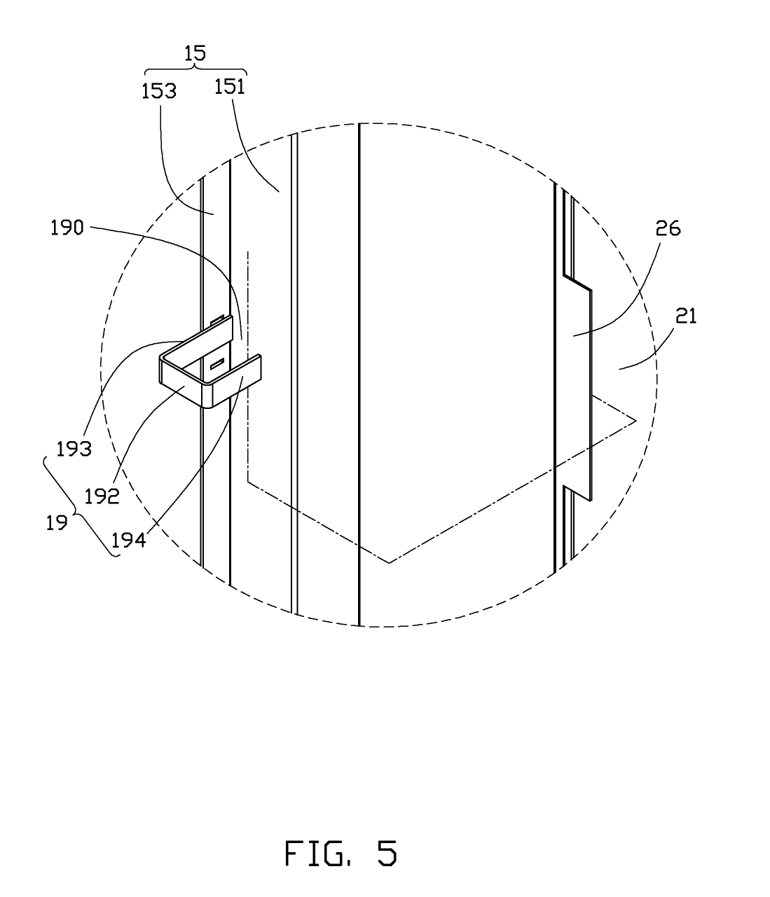

Each of the supporting posts 15 has a top end connected to a corner of the top frame 11, and a bottom end connected to a corner of the bottom frame 13. Referring also to FIG. 5, each of the supporting posts 15 includes an elongated first vertical plate 151, and an elongated second vertical plate 153 perpendicular to the first vertical plate 151. A width of each of the first vertical plates 151 as measured parallel to a front-to-rear axis of the rack 10 exceeds a corresponding width of each of the first angle frames 110 (FIG. 3), and substantially equals a corresponding width of each of the third angle frames 130 (FIG. 4). The second vertical plate 153 extends from an inner side of the first vertical plate 151. Each of the first angle frames 110 is connected between two neighboring supporting posts 15, with two opposite ends of the first angle frame 110 respectively abutting inner portions, adjacent to the second vertical plates 153, of the first vertical plates 151 of the two neighboring supporting posts 15. An outer portion of each of the first vertical plates 151 away from the second vertical plate 153 functions as a smooth guiding surface along which the side door 20 slides.

Referring also to FIG. 5, a latch hook 19 is mounted in the center of each of the supporting posts 15. The latch hook 19 is substantially U-shaped. The latch hook 19 includes a connecting arm 192, and a first arm 193 and a second arm 194 extending from two opposite ends of the connecting arm 192, respectively. The first arm 193 is affixed to the second vertical plate 153. The second arm 194 is adjacent to the side door 20. The latch hook 19 defines an opening 190 between the first and second arms 193, 194. The openings 190 of the latch hooks 19 mounted on the supporting posts 15 at opposite sides of the first angle frame 110 are positioned along a same axis, but oriented in mutually opposite directions.

The two side doors 20 are mounted at front and rear sides of the rack 10, respectively, and each side door 20 is coupled to two of the supporting posts 15. Each side door 20 includes a rectangular main board 21, a top flange 23 extending inward from a top side of the main board 21, a bottom flange 25 extending inward from a bottom side of the main board 21, and two fastening plates 26 extending inward from middle portions of left and right sides of the main board 21, respectively.

Referring to FIG. 3 again, two mounting holes 230, corresponding to the vertical strips 162 of the fastening tabs 16 of the first angle frame 110 respectively, are defined in the top flange 23. Referring to FIG. 4 again, a plurality of locating holes 250, corresponding to the connecting strips 18 of the third angle frame 130, respectively, is defined in the bottom flange 25. Referring to FIG. 5 again, the fastening plates 26 correspond to the latch hooks 19 of the supporting posts 15, respectively. The fastening plates 26 are received in the latch hooks 19 to fix the side door 20 and the supporting posts 15. A height of the fastening plates 26 of the rack 10 exceeds that of the second arms 194 of the latch hooks 19. Two handles 27 level with each other are formed in the center of the main board 21, respectively. Each of the handles 27 includes a bent, recessed holding portion 271 recessed from an outer surface of the main board 21 towards the rack 10. Two rectangular through holes 270 corresponding to the holding portions 271 are defined at the outer surface of the main board 21. When the side door 20 is assembled to or detached from the rack 10, the holding portions 271 of the handles 27 can be accessed via the through holes 270 to provide convenient attachment of the side door 20 to the rack 10 or convenient detachment of the side door 20 from the rack 10.

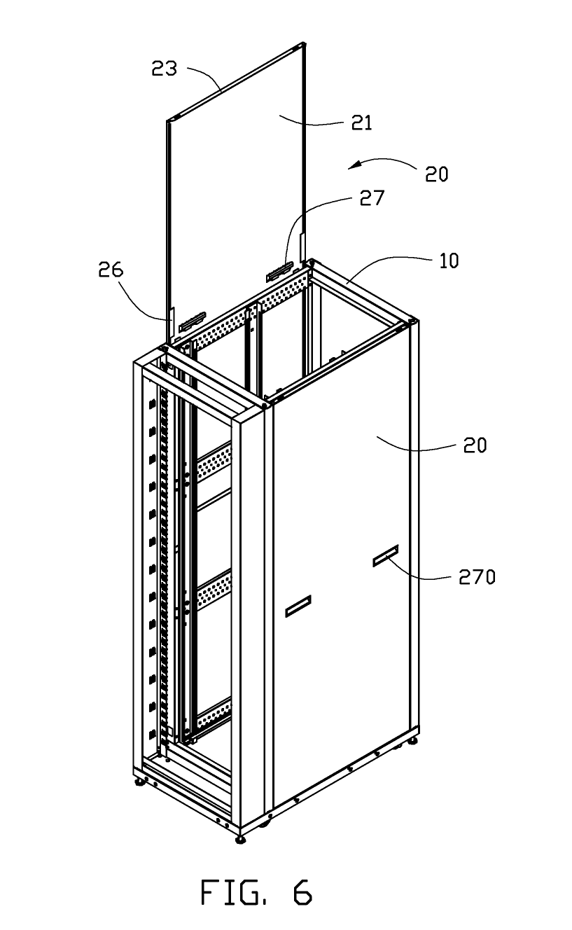

Referring back to FIG. 1, details of assembly of one of the side doors 20 to the rack 10 are as follows. In particular, the side door 20 to be mounted to the rear side of the rack 10 is taken as an example. The side door 20 is positioned above the rack 10, with the left and right sides of the side door 20 aligned with the first vertical plates 151 of the two supporting posts 15 located at the rear side of the rack 10, respectively. The locating holes 250 of the bottom flange 25 of the side door 20 align with the connecting strips 18 of the third angle frame 130, respectively. The mounting holes 230 of the top flange 23 of the side door 20 align with the vertical strips 162 of the fastening tabs 16 of the first angle frame 110, respectively. Referring also to FIG. 6, the side door 20 is pushed downward, with the left and right sides of the side door 20 abutting and sliding along the first vertical plates 151 of the two supporting posts 15, respectively, until the bottom flange 25 of the side door 20 contacts the third angle frame 130. The bottom flange 25 and the third angle frame 130 are connected to each other via engagement of the connecting strips 18 in the locating holes 250, respectively. The top flange 23 of the side door 20 and a top surface of the first angle frame 110 are coplanar. The top flange 23 and the first angle frame 110 are connected to each other via the engagement of vertical strips 162 of the fastening tabs 16 in the mounting holes 230, respectively.

A distance between the fastening plates 26 and the main board 21 of the side door 20 exceeds a distance between the second arms 194 of the latch hooks 19 and the main board 21, but is less than a distance between the first arms 193 of the latch hooks 19 and the main board 21. With this configuration, the fastening plates 26 can be received in the latch hooks 19 of the two supporting posts 15, respectively, followed by the side door 20 sliding downward along the supporting posts 15, thereby fixing the side door 20 and the supporting posts 15 together. At the locking position, each of the fastening plates 26 is sandwiched between the first and second arms 193, 194 of a corresponding latch hook 19. One side of the second arm 194 adjacent to the first arm 193 abuts a middle portion of one side of the fastening plate 26 adjacent to the main board 21. The fastening plates 26 and the latch hooks 19 cooperatively limit front-to-rear axis movement between the side door 20 and the rack 10. Simultaneously, the first vertical plates 151 of the two supporting posts 15 cooperatively limit left-to-right axis movement between the side door 20 and the rack 10. Alternatively, the positions of the fastening plates 26 and the latch hooks 19 can be exchanged. That is, the fastening plates 26 can be formed at the supporting posts 15, and the latch hooks 19 can be formed at the side door 20.

Detachment of the side door 20 from the rack 10 requires an upward force applied to the side door 20 to disengage the connecting strips 18 from the locating holes 250 of the bottom flange 25 and the vertical strips 162 of the fastening tabs 16 from the mounting holes 230 of the top flange 23, respectively. The side door 20 is further pulled upwardly along the first vertical plates 151 of the two supporting posts 15, moving the fastening plates 26 upwardly relative to the latch hooks 19 and eventually withdrawing the fastening plates 26 from the latch hooks 19. Thus, the side door 20 is detached from the rack 10. Accordingly, the side door 20 can be easily assembled to or detached from the rack 10 without any tools, which makes assembly and disassembly of the server cabinet 100 simple and convenient.

It is to be understood, however, that even though numerous characteristics and advantages of the exemplary embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A server cabinet comprising:
a rack adapted for accommodating a plurality of servers therein, the rack comprising a top frame, a bottom frame spaced from the top frame, and a plurality of supporting posts connected between the top frame and the bottom frame; and
a side door mounted between two of the supporting posts, a latch hook provided on one of the side door and one of the two supporting posts, a fastening plate corresponding to the latch hook provided on the other one of the side door and the one of the two supporting posts;
wherein, during assembly of the side door to the rack, the side door slides between the two supporting posts with two opposite sides of the side door abutting the two supporting posts, respectively, until the fastening plate is received in the latch hook and the side door is thereby engaged between the two supporting posts.

2. The server cabinet of claim 1, wherein, during detachment of the side door from the rack, the side door slides between the two supporting posts with the two opposite sides of the side door abutting the two supporting posts, respectively, until the fastening plate withdraws from the latch hook and the side door is thereby disengaged from the two supporting posts.

3. The server cabinet of claim 1, wherein the latch hook is provided on the supporting post, and the fastening plate is provided on the side door.

4. The server cabinet of claim 3, wherein the latch hook is substantially U-shaped.

5. The server cabinet of claim 4, wherein the latch hook comprises a connecting arm, from two opposite ends of which a first arm and a second arm extend, respectively.

6. The server cabinet of claim 5, further comprising another latch hook and another fastening plate corresponding thereto, wherein the latch hooks are mounted at the two supporting posts, respectively, and the fastening plates extend from the two opposite sides of the side door, respectively.

7. The server cabinet of claim 6, wherein each of the supporting posts comprises a first vertical plate and a second vertical plate perpendicular thereto, the opening of each of the latch hooks facing the first vertical plate of a corresponding supporting post, and the two opposite sides of the side door abutting the first vertical plates of the two neighboring supporting posts, respectively.

8. The server cabinet of claim 7, wherein the openings of the two latch hooks are positioned along a same axis, but oriented in mutually opposite directions.

9. The server cabinet of claim 1, wherein the latch hook is provided on the side door, and the fastening plate is provided on the supporting post.

10. The server cabinet of claim 1, wherein the top frame comprises a top angle frame connected between top ends of the two supporting posts, the top angle frame forming a fastening tab at an outer side thereof, the side door comprising a top flange extending outward from a top side towards the rack, and a mounting hole for receiving the fastening tab defined in the top flange.

11. The server cabinet of claim 7, wherein the bottom frame comprises a bottom angle frame connected between bottom ends of the two supporting posts, the bottom angle frame forming a connecting strip thereof, the side door comprising a bottom flange extending outward from a bottom side towards the rack, and a locating hole for receiving the connecting strip defined in the bottom flange.

12. The server cabinet of claim 1, wherein the fastening plate and the latch hook are engaged, cooperatively limiting relative movement between the side door and the rack along a first axis, and the two supporting posts cooperatively limiting relative movement between the side door and the rack along a second axis, and the side door moveable relative to the supporting posts along a third axis, wherein any two of the first, second and third axes are perpendicular.

13. A server cabinet comprising:
a rack adapted for accommodating a plurality of servers therein, the rack comprising two supporting posts; and
a side door mounted between the two supporting posts, a pair of latch hooks provided on the side door or on the two supporting posts, a pair of fastening plates corresponding to the latch hooks provided on the two supporting posts or on the side door;
wherein, during assembly of the side door to the rack, the side door slides between the two supporting posts with two opposite sides of the side door abutting the two supporting posts, respectively, until the fastening plates are received in the latch hooks respectively and the side door is thereby engaged between the two supporting posts.

14. The server cabinet of claim 13, wherein, during detachment of the side door from the rack, the side door slides between the two supporting posts with the two opposite sides of the side door abutting the two supporting posts, respectively, until the fastening plate withdraws from the latch hook and the side door is thereby disengaged from the two supporting posts.

15. The server cabinet of claim 14, wherein each of the latch hooks is substantially U-shaped, and comprises a connecting arm, from two ends of which a first arm and a second arm extend, respectively.

16. The server cabinet of claim 15, wherein the latch hooks are mounted at the two supporting posts, respectively, and the fastening plates extending from the two opposite sides of the side door, respectively.

17. The server cabinet of claim 16, wherein each of the supporting posts comprises a first vertical plate and a second vertical plate perpendicular thereto, an opening of each of the latch hooks adjacent to the first vertical plate of a corresponding supporting post, the two opposite sides of the side door abutting the first vertical plates, respectively.

18. The server cabinet of claim 13, wherein the pair of the fastening plates are provided on the two supporting posts, respectively, and the pair of the latch hooks are provided on the side door.

19. The server cabinet of claim 13, wherein the rack comprises an angle frame connected between top ends of the two supporting posts, the angle frame forming a fastening tab at an outer side thereof, the side door comprising a top flange extending outward from a top side towards the rack, a mounting hole for receiving the fastening tab defined in the top flange.

20. The server cabinet of claim 19, wherein the rack comprises another angle frame connected between bottom ends of the two supporting posts, the another angle frame forming a connecting strip extending upwardly therefrom, the side door comprising a bottom flange extending outward from a bottom side towards the rack, and a locating hole for receiving the connecting strip defined in the bottom flange.
